(19) United States
(12) Patent Application Publication
(10) Pub. No.: US 2007/0154623 A1
(43) Pub. Date: Jul. 5, 2007

(54) Method for manufacturing single-walled carbon nanotube on glass

(76) Inventors: Yo-sep Min, Yongin-si (KR); Eun-ju Bae, Yongin-si (KR); Wan-jun Park, Seoul (KR)

Correspondence Address: CANTOR COLBURN, LLP, 55 GRIFFIN ROAD SOUTH, BLOOMFIELD, CT, 06002, US

(21) Appl. No.: 11/471,262

(22) Filed: Jun. 20, 2006

(30) Foreign Application Priority Data
Dec. 29, 2005 (KR) 2005-0134405

(51) Int. Cl. B05D 5/12; C23C 16/00; H05H 1/24

(52) U.S. Cl. 427/64; 427/569; 427/248.1; 427/299

(57) ABSTRACT

A method for manufacturing high-quality single-walled carbon nanotubes on a glass substrate at relatively low temperatures includes: depositing a buffer layer on a glass substrate; depositing a catalytic metal on the buffer layer; placing the glass substrate having the catalytic metal formed thereon in a vacuum chamber and generating H₂O plasma inside the vacuum chamber; and supplying a source gas into the vacuum chamber and growing a carbon nanotube on the glass substrate.

This application claims priority to Korean Patent Application No. 2005-134405, filed Dec. 29, 2005, and all the benefits accruing therefrom under 35 U.S.C. §119, the contents of which in its entirety are herein incorporated by reference.

### BACKGROUND OF THE INVENTION

1. Field of the Invention

The present invention relates to a method for manufacturing a carbon nanotube (“CNT”), and more particularly, to a method for manufacturing a CNT by growing a high-quality single-walled CNT on a glass substrate at a relatively low temperature.

2. Description of the Related Art

A CNT is an allotrope of carbon made of carbon-atom clusters. A CNT is a hexagonal network (e.g., beehive) of carbon atoms, which is rolled to form a tube shape. The CNT is an extremely small substance having a diameter of a few nanometers.

There are two main types of nanotubes, a single-walled nanotube (“SWNT”) and a multiwall nanotube (“MWNT”). A single-wall carbon nanotube has only a single carbon atom layer, whereas a multiwall carbon nanotube is composed of multiple carbon atom layers. SWNTs are more flexible than MWNTs, so they tend to mass as a rope. These SWNTs are called rope nanotubes.

The structure of a carbon nanotube can be conceptualized by wrapping a sheet of graphite into a tube having a diameter of a few nanometers, and is composed entirely of sp² bonds. Depending on the roll angle and shape of the graphite surface, carbon nanotubes can have extremely high electrical conductivity or semiconductivity depending on their chirality. In addition, carbon nanotubes have high mechanical strength, elastic mechanical properties and are chemically very stable. These characteristics contribute to excellent mechanical properties, high selectivity, outstanding field emission properties, and high efficiency storage medium for hydrogen gas of carbon nanotubes.

However, there are certain conditions that must be met in order to meet the needs of a wide variety of applications for such carbon nanotubes. For instance, to apply a carbon nanotube onto a glass substrate for display, it is necessary to grow high-purity SWNTs on a large-size glass substrate. Especially in cases of using a thermal chemical vapor deposition (“CVD”) method or plasma enhanced chemical vapor deposition (“PECVD”) method for growing carbon nanotubes on the glass substrate, carbon nanotubes are typically grown at low temperatures. However, since the transformation temperature of glass for a display device is about 666° C. where as the growth temperature of SWNTs is higher than 700° C., the glass itself may be easily transformed during the growth of the SWNTs.

Moreover, when SWNTs are grown on the glass substrate, the glass and carbon react together and as a result, MWNTs are often formed. Even though SWNTs may have been generated, their purity is very low. These problems made it difficult to grow SWNTs on the glass substrate.

### BRIEF SUMMARY OF THE INVENTION

It is, therefore, an aspect of the present invention to provide a method for manufacturing high-purity single-walled carbon nanotubes on a glass substrate at relatively low temperatures.

To achieve the above aspect and other aspects and advantages, a method for manufacturing single-walled carbon nanotubes on glass is provided. The method includes depositing a buffer layer on a glass substrate, depositing a catalytic metal on the glass substrate having the buffer layer formed thereon, placing the glass substrate having the catalytic metal formed thereon in a vacuum chamber and generating H₂O plasma inside the vacuum chamber, and supplying source gas into the vacuum chamber and growing a carbon nanotube on the glass substrate.

In exemplary embodiments, the buffer layer includes a transparent amorphous material having a relatively high negative value of heat of formation. The buffer layer includes at least one compound selected from the group consisting of: Al₂O₃, SiO₂, HfO₂, ZrO₂, Ta₂O₅, Y₂O₅ and Nb₂O₅. More preferably includes Al₂O₃ or SiO₂. Also, the buffer layer has a thickness of about 100 nm or more.

The catalytic metal is at least one member selected from the group consisting of Fe, Ni, Co and alloys thereof. In exemplary embodiments, the catalytic metal has a thickness of about 10 nm or less.

In addition, the H₂O plasma is controlled with about 80 W of power.

The source gas for use in the carbon nanotube growth is at least one member selected from the group consisting of C₂H₂, CH₄, C₂H₄, C₂H₆ and CO. In exemplary embodiments, the source gas is supplied at a flow rate ranging from about 20 sccm to about 60 sccm. Moreover, the carbon nanotubes are grown at temperatures below the transformation temperature of the glass substrate. In exemplary embodiments, the carbon nanotubes are grown at a temperature ranging from about 450° C. to about 650° C. Here, the carbon nanotube growth is performed for about 10 seconds to about 600 seconds.

### BRIEF DESCRIPTION OF THE DRAWINGS

The above aspects and features of the present invention will be more apparent by describing certain exemplary embodiments of the present invention with reference to the accompanying drawings, in which:

FIG. 1 is a mimetic diagram illustrating an exemplary embodiment of a substrate on which single-walled carbon nanotubes (SWNTs) are grown, according to the present invention;

FIG. 2 is a schematic view of an exemplary embodiment of a device for manufacturing SWNTs, according to the present invention;

FIG. 3A and FIG. 3B are scanning electron microscope (“SEM”) images showing SWNTs according to Example 1 and Comparative Example 2, respectively;

FIG. 4 is a graph showing Raman spectra of SWNTs according to Example 1 and Comparative Example 2, respectively;

FIG. 5 is a high-resolution transmission electron microscope (“TEM”) image showing an enlarged SWNT according to Example 1; and

FIGS. 6A to 6D are high-resolution TEM images of CoFe thin films with different thicknesses, in which CoFe is a catalytic metal for growth of SWNTs. FIGS. 6E to 6L are SEM images of carbon nanotubes according to Examples 2 to 9, which are grown on the CoFe thin film layers of FIGS. 6E to 6L, respectively.

### DETAILED DESCRIPTION OF THE INVENTION

The invention is described more fully hereinafter with reference to the accompanying drawings, in which exemplary embodiments of the invention are shown. The invention may, however, be embodied in many different forms and should not be construed as limited to the exemplary embodiments set forth herein. Rather these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

The terminology used herein is for the purposes of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Also, well-known functions or constructions are not described in detail since they would obscure the invention in unnecessary detail.

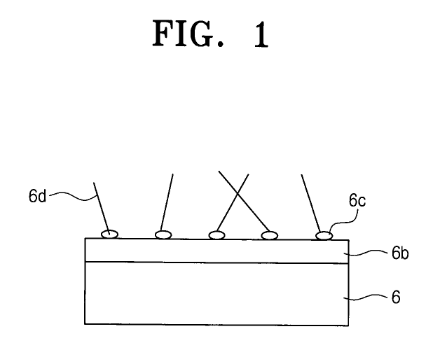

FIG. 1 illustrates an exemplary embodiment of a substrate on which single-walled carbon nanotubes (“SWNTs”) are grown, according to the present invention. Referring to FIG. 1, a glass substrate 6 for use in growing SWNTs 6d is first prepared, and a buffer layer 6b is deposited on the substrate 6. The buffer layer 6b is for buffering the activity of a catalyst between the glass substrate 6 and a catalytic metal 6c (to be described). To this end, the buffer layer 6b has a thickness of about 100 nm or more. The buffer layer 6b can be formed by a deposition or sputtering method, or by generating RF plasma. The buffer layer 6b is made of a transparent material suitable for use for a display glass substrate. Desirably, amorphous material having a relatively high negative value of heat of formation is used for the buffer layer 6b. Table 1 below shows such suitable transparent materials and their corresponding heats of formation. Among those shown in Table 1, Al₂O₃ or SiO₂ is preferred. When the buffer layer is made of Al₂O₃, the manufacturing process conditions of the SWNTs can be broadened.

TABLE 1

| Oxide | Heat of Formation (KJ/mol) |
|---|---|
| Al₂O₃ | −1675.7 |
| SiO₂ | −910.7 |
| HfO₂ | −1144.7 |
| ZrO₂ | −1100.6 |
| Ta₂O₅ | −2046.0 |
| Y₂O₅ | −1905.3 |
| Nb₂O₅ | −1899.5 |

Next, a catalytic metal 6c is formed on the buffer layer 6b. The catalytic metal 6c can be deposited on the buffer layer 6b by thermal deposition, sputtering or spin coating. Examples of the catalytic metal include Fe, Ni, Co or alloys thereof. The catalytic metal layer 6c (or simply the catalytic layer 6c) has a thickness of about 10 nm or less. If the catalytic metal layer 6c is too thick, multi-wall nanotubes (“MWNTs”) are easily formed, or even if the SWNTs are formed, the purity thereof is easily deteriorated.

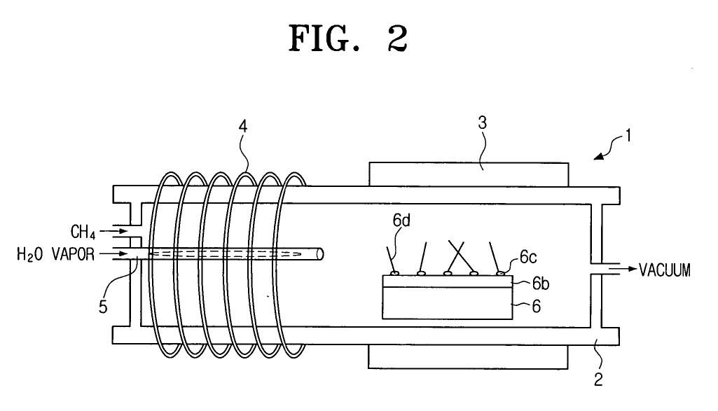

After the catalytic metal 6c is deposited on the buffer layer 6b, a device 1 shown in FIG. 2 is used to grow the carbon nanotubes 6d on the glass substrate 6 where the catalytic metal 6c is formed.

FIG. 2 is a schematic view of the device 1 for manufacturing SWNTs. More specifically, the device 1 is a kind of lamp-heating type radio frequency remote PECVD system. As shown in FIG. 2, the device 1 includes a vacuum chamber 2, a heating furnace 3 and a radio frequency (“RF”) plasma coil 4. The vacuum chamber 2 is desirably made of a quartz material. The RF plasma coil 4 for generating plasma is installed at one side of the vacuum chamber 2, and the heating furnace 3 for heating the vacuum chamber 2 to a predetermined temperature is installed at the other side of the vacuum chamber 2. In addition, a 10 mm-long and thin quartz tube 5 is installed inside the vacuum chamber 2. and H₂O vapor is supplied into the vacuum chamber 2 through the quartz tube 5.

In order to grow the carbon nanotubes 6d on the glass substrate 6 using the above-described device 1, it is necessary to place the substrate 6 having the catalytic metal 6c deposited on the buffer layer 6b in the vacuum chamber 2. Then, the vacuum chamber 2 is provided with H₂O vapor through the quartz tube 5 and heated gradually to a temperature for growing carbon nanotubes. Desirably, the growth temperature is kept below the transformation temperature of the glass substrate 6, more desirably, in a range from about 450° C. to 650° C.

Next, RF power is applied to the RF plasma coil 4 to discharge H₂O plasma from the quartz tube 5. Here, the RF plasma power is desirably about 80 W or less.

Finally, the source gas is provided to the vacuum chamber 2 and thus, the carbon nanotubes 6d grow on the glass substrate 6 under the H₂O plasma atmosphere. Examples of the source gas used for synthesizing carbon nanotubes 6d include C₂H₂, CH₄, C₂H₄, C₂H₆, CO and the like. Desirably, the source gas is supplied at a flow rate from about 20 standard centimeter cube per minute (“sccm”) to about 60 sccm for 10 to 600 seconds to ensure that the carbon nanotubes 6d fully grow.

In the present invention, SWNTs 6d grow on the glass substrate 6 by a CVD method under H₂O plasma atmosphere. Here, H₂O plasma acts as a mild oxidant or mild echant during growth of the carbon nanotubes, and removes carbonaceous impurities. Particularly, in the case of growing carbon nanotubes on the glass substrate under H₂O plasma atmosphere as in the present invention, the carbon nanotubes can grow at relatively lower temperatures than the glass transformation temperature. Therefore, according to the present invention, it becomes possible to substantially reduce the amount of impurities, e.g., amorphous carbon, which are produced during growth of the carbon nanotubes at a temperature higher than 800° C. as in the prior art. Especially, since SWNTs grow at low temperatures, high purity carbon nanotubes with a highly crystalline structure are obtained. Needless to say, these carbon nanotubes can be very advantageously used for a display panel.

The following will now describe exemplary examples of the present invention.

### EXAMPLES

### Example 1

A SiO₂ thin film of about 200 nm in thickness was formed on a flat panel display glass (Corning 1737, manufactured by Samsung Corning Company Ltd.). In detail, while 30 W was applied to generate RF plasma, SiH₄ with a gas flow of about 530 sccm and N₂O with a gas flow of 320 sccm were introduced, respectively, and the SiO₂ thin film was deposited on the flat panel display glass by a CVD method at almost 320° C.

Next, using a CoFe target (Co:Fe=9:1), the SiO₂ thin film deposition process continued for 9 seconds with about 200 W RF plasma power by RF magnetron sputtering to form a 4.0 nm-thick CoFe catalytic layer on the buffer layer.

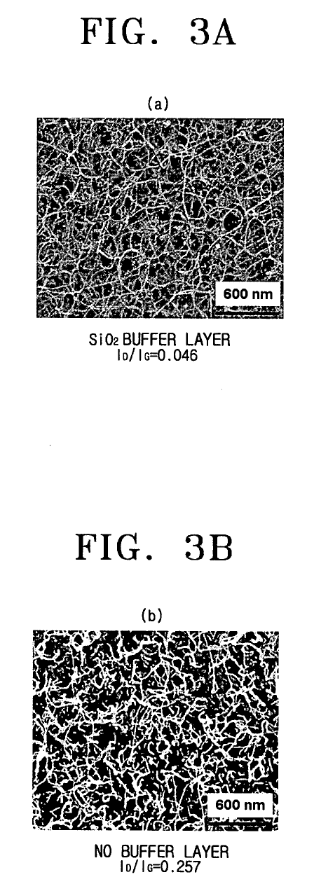

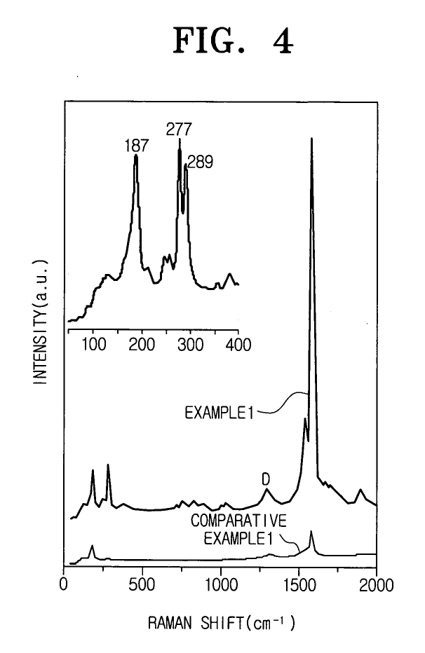

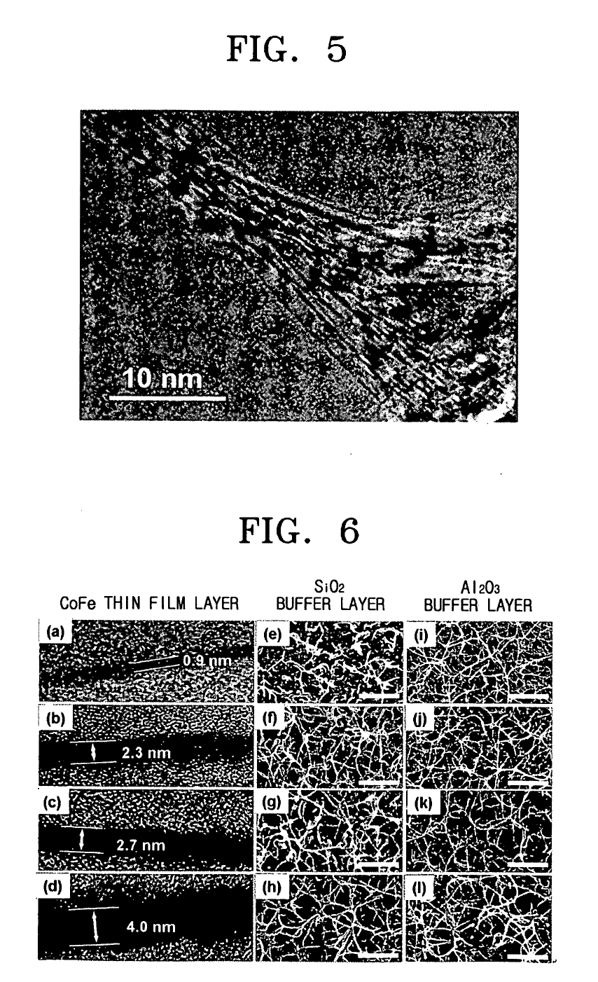

The glass substrate coated with the CoFe catalytic layer was then placed in the lamp-heating type radio frequency remote PECVD system shown in FIG. 2 for growing carbon nanotubes at a temperature of about 550° C. As for the source gas, methane gas with a gas flow of about 60 sccm was supplied to the system, and approximately 15 W was applied to the system for generating H₂O plasma. Under these conditions, carbon nanotubes grew inside the system for 300 seconds. Scanning electron microscope (“SEM”) images of the manufactured carbon nanotubes are illustrated in FIGS. 3a and 5, respectively.

### Comparative Example 1

The same kind of glass as in Example 1 was used. In this case, however, a 4.0 nm-thick CoFe catalytic layer was deposited directly on the surface of the glass and the SiO₂ buffer layer was not used at all. The same method as in Example 1 was used again to grow carbon nanotubes. FIG. 3B shows an SEM image of such a resulting carbon nanotube.

As illustrated in FIGS. 3a and 5, the SiO₂ buffer layer in Example 1 served to enhance density and quality of SWNTs. FIG. 5 especially illustrates that the CVD grown carbon nanotubes are primarily bundles of SWNTs.

On the other hand, as shown in FIG. 3B, when SWNTs grow under the conditions of Comparative Example 1 (i.e., without a buffer layer), both the density of SWNTs is much lower and more carbon impurities exist compared to Example 1, which is evident with reference to FIG. 4.

FIG. 4 is a graph showing Raman spectra (e.g., 633 nm laser diode) of SWNTs according to Example 1 and Comparative Example 1, respectively. In FIG. 4, a thick solid line and a thin solid line show Raman spectra for the SWNTS of Example 1 and Comparative Example 1, respectively, and the graph of the upper left side of FIG. 4 is an enlarged view thereof in radial breathing mode (“RBM”). Still referring to FIG. 4, the intensity of Comparative Example 1 without a buffer layer is very weak, compared to Example 1 with a buffer layer. In addition, according to the Raman spectra in FIG. 4, the intensity ratio of D band to G band (I_{D}/I_{G}) of Example 1 was 0.046, whereas the intensity ratio of Comparative Example 1 was 0.257, which is very large. This result illustrates that Comparative Example 1, unlike Example 1, has a low purity because of disordered graphites and amorphous carbon existing together with CVD grown carbon nanotubes.

### Example 2

The same method as in Example 1 was used for growing carbon nanotubes, except that the SiO₂ thin film deposition process was performed using a CoFe target (Co:Fe=9:1) for 10 seconds with about 50 W RF plasma power by RF magnetron sputtering, in order to form a 0.9 nm-thick CoFe catalytic layer on the buffer layer.

FIG. 6a is a transmission electron microscope (“TEM”) image of the CoFe catalytic layer, and FIG. 6e is an SEM image of the resulting carbon nanotube.

### Example 3

The same method as in Example 1 was used for growing carbon nanotubes, except that the SiO₂ thin film deposition process was performed using a CoFe target (Co:Fe=9:1) for 10 seconds with about 70 W RF plasma power by RF magnetron sputtering, in order to form a 2.3 nm-thick CoFe catalytic layer on the buffer layer.

FIG. 6b is a TEM image of the CoFe catalytic layer, and FIG. 6f is an SEM image of the resulting carbon nanotube.

### Example 4

The same method as in Example 1 was used for growing carbon nanotubes, except that the SiO₂ thin film deposition process was performed using a CoFe target (Co:Fe=9:1) for 10 seconds with about 100 W RF plasma power by RF magnetron sputtering, in order to form a 2.7 nm-thick CoFe catalytic layer on the buffer layer.

FIG. 6c is a TEM image of the CoFe catalytic layer, and FIG. 6g is an SEM image of the resulting carbon nanotube.

### Example 5

The same method as in Example 1 was used for growing carbon nanotubes.

FIG. 6d is a TEM image of the CoFe catalytic layer, and FIG. 6h is an SEM image of the resulting carbon nanotube.

### Example 6

The same method as in Example 2 was used for growing carbon nanotubes, except that an Al₂O₃ thin film was used as the buffer layer.

The Al₂O₃ thin film was obtained from the reaction between trimethylaluminum (TMA) and water at a temperature of about 400° C. by atomic layer deposition (“ALD”), and has a thickness of 200 nm. The TMA and water were reacted under a vacuum of 0.8 Torr in the following order of TMA injection for 0.5 second-5 seconds of purging, H₂O injection for 2 seconds-5 seconds of purging. FIG. 6i is an SEM image of the resulting carbon nanotube.

### Example 7

The same method as in Example 3 was used for growing carbon nanotubes, except that an Al₂O₃ thin film was used as the buffer layer. FIG. 6j is an SEM image of the resulting carbon nanotube.

### Example 8

The same method as in Example 4 was used for growing carbon nanotubes, except that an Al₂O₃ thin film was used as the buffer layer. FIG. 6k is an SEM image of the resulting carbon nanotube.

### Example 9

The same method as in Example 5 was used for growing carbon nanotubes, except that an Al₂O₃ thin film was used as the buffer layer. FIG. 61 is an SEM image of the resulting carbon nanotube.

FIGS. 6A to 6D are high-resolution TEM images of CoFe thin films with different thicknesses, in which CoFe is a catalytic metal for growth of SWNTs, according to Examples 2 to 5. Moreover, FIGS. 6E to 6L are SEM images of carbon nanotubes according to Examples 2 to 9, which are grown on the CoFe thin film layers of FIGS. 6E to 6L of Examples 2 to 5, respectively. The images of FIGS. 6a to 6l are presented in a bar scale.

As shown in FIGS. 6E to 6L, when carbon nanotubes grow on the glass substrate having the SiO₂ or Al₂O₃ buffer layer deposited thereon as in Examples 2 to 9, SWNTs can be evenly formed. In particular, as shown in FIGS. 6e to 6h, the SWNTs grown on the SiO₂ buffer layer as in Examples 2 to 5 are more dense if the thickness of the CoFe thin film layer formed on the SiO₂ buffer layer is increased. Meanwhile, as shown in FIGS. 6i to 6l, the SWNTs grown on the Al₂O₃ buffer layer as in Examples 6 to 9 are not affected much by a varying thickness of the CoFe thin film layer. In other words, since the growth of SWNTs is not affected by the thickness of the CoFe thin film layer, provided that the Al₂O₃ buffer layer is formed on the glass substrate, the manufacturing conditions of SWNTs are broadened to that extent.

As described herein, according to the present invention, it is possible to grow high-quality SWNTs at relatively low temperatures. That is, carbon nanotubes grown at a low temperature range result mostly in SWNTs being formed with a few MWNTs being formed. Further, the SWNTs of the present invention not only contain a considerably low amount of carbon impurities, but the SWNTs also have a highly crystalline structure. Therefore, these carbon nanotubes can be advantageously used for a display panel and a semiconductor element.

Although the exemplary embodiments of the present invention have been described, it will be understood by those skilled in the art that the present invention should not be limited to the described exemplary embodiments, but various changes and modifications can be made within the spirit and scope of the present invention as defined by the appended claims.

What is claimed is:

1. A method for manufacturing single-walled carbon nanotubes on glass, comprising:
depositing a buffer layer on a glass substrate;
depositing a catalytic metal on the buffer layer;
placing the glass substrate having the catalytic metal formed thereon in a vacuum chamber and generating H₂O plasma inside the vacuum chamber; and
supplying a source gas into the vacuum chamber and growing a carbon nanotube on the glass substrate.

2. The method of claim 1, wherein the buffer layer comprises a transparent amorphous material having a relatively high negative value of heat of formation.

3. The method of claim 2, wherein the buffer layer comprises at least one compound selected from the group consisting of: Al₂O₃, SiO₂, HfO₂, ZrO₂, Ta₂O₅, Y₂O₅ and Nb₂O₅.

4. The method of claim 2, wherein the buffer layer comprises SiO₂.

5. The method of claim 2, wherein the buffer layer comprises Al₂O₃.

6. The method of claim 1, wherein the buffer layer has a thickness of 100 nm or more.

7. The method of claim 1, wherein the catalytic metal is at least one member selected from the group consisting of Fe, Ni, Co and alloys thereof.

8. The method of claim 1, wherein the catalytic metal has a thickness of about 10 nm or less.

9. The method of claim 1, wherein the H₂O plasma is controlled with about 80 W of power.

10. The method of claim 1, wherein the source gas is at least one member selected from the group consisting of C₂H₂, CH₄, C₂H₄, C₂H₆ and CO.

11. The method of claim 10, wherein the source gas is supplied at a flow rate ranging from about 20 sccm to about 60 sccm.

12. The method of claim 1, wherein the carbon nanotubes are grown at a temperature below the transformation temperature of the glass substrate.

13. The method of claim 12, wherein the carbon nanotubes are grown at a temperature ranging from about 450° C. to about 650° C.

14. The method of claim 1, wherein the carbon nanotube growth is performed for about 10 seconds to about 600 seconds.
